(19) United States
(12) Patent Application Publication
(10) Pub. No.: US 2025/0365894 A1
(43) Pub. Date: Nov. 27, 2025

(54) PASSIVE COOLING SYSTEM FOR RADIOFREQUENCY COMPONENTS

(71) Applicant: Rockwell Collins, Inc., Cedar Rapids, IA (US)

(72) Inventors: Jose O. VASQUEZ, Cedar Rapids, IA (US); Sonali GOYAL, Cedar Rapids, IA (US); Jason GRAHAM, Cedar Rapids, IA (US); Alexander MAYORGA, Richardson, TX (US)

(73) Assignee: Rockwell Collins, Inc., Cedar Rapids, IA (US)

(21) Appl. No.: 18/672,738

(22) Filed: May 23, 2024

(51) Int. Cl. H05K 7/20

(52) U.S. Cl. CPC H05K 7/20327

(57) ABSTRACT

A cooling system and method for passively cooling a guidance system having at least one active radio frequency component, a solid-liquid phase change material (SL-PCM), and a thermal expansion chamber. The SL-PCM absorbs heat from the active radio frequency component and is converted from a solid phase to a liquid phase. While in liquid phase the SL-PCM is transported into the thermal expansion chamber via capillary action through various structures.

### FIELD OF THE INVENTION

The present application relates to a closed passive cooling system and method for small scale radiofrequency (RF) components, and a phase changing passive heat sink device to achieve the passive cooling for small scale RF components.

### BACKGROUND

Long range precision guided munitions are requiring an ever-increasing amount of thermal management to reach their targets at extended ranges, due to active RF components being included in the small guidance package. The RF components in the guidance systems produce large amounts of heat during operation which impacts guidance electronics and hardware. Small scale RF components can overheat which in turn can negatively impact performance due to the resultant high thermal loads. Many traditional heat-sinking methods, for example, heat sinks made from metals, are not feasible for cooling such RF components as they can significantly interfere with RF reception and transmission.

Therefore, there is an unsatisfied need for a material or device which can enable passive cooling of small-scale RF components, and a system and method for cooling small scale RF components.

### SUMMARY OF THE INVENTION

In one embodiment of the present disclosure, a system, for example, a cooling system is provided which includes at least one active radio frequency component, a solid-liquid phase change material (SL-PCM) which is non-electrically conductive, and a thermal expansion chamber. The SL-PCM is positioned between the active radio frequency component and the thermal expansion chamber, and is in thermal conductive contact with the active radio frequency component.

In some embodiments, the thermal expansion chamber is separated from the SL-PCM by a wall, where the wall includes at least one pore, wick, or a combination thereof. The at least one pore and wick have a pore size equal to the SL-PCM surface tension quality. The system may additionally include a reservoir where the reservoir surrounds the SL-PCM.

The reservoir and the thermal expansion chamber may be separated by a wall wherein the wall includes at least one pore, wick, or a combination thereof. The reservoir and at least one active radio frequency component may be separated by at least one wall where the wall includes at least one pore, wick, or a combination thereof,

In some embodiments, reservoir may be comprised of a porous material having a pore size equal to the SL-PCM surface tension quality.

The system may also include a housing which encapsulates the at least one active radio frequency component, SL-PCM, and thermal expansion chamber. In some embodiments, the thermal expansion chamber adjacent to the inner wall of the housing.

The thermal expansion chamber may be spaced from the housing and the at least one active radio frequency component by the SL-PCM.

The system may also include a reservoir wherein the reservoir surrounds the SL-PCM, where the thermal expansion chamber is spaced from the housing and the at least one active radio frequency component by the reservoir.

In another embodiment of the of the present disclosure, a method for passively cooling a guidance system is provided. The method includes absorbing thermal energy from at least one active radio frequency component with a solid-liquid phase change material (SL-PCM), changing the phase of the SL-PCM from a solid to a liquid, and moving the SL-PCM to a thermal expansion chamber.

The SL-PCM may be moved to the thermal expansion chamber via capillary action through at least one pore, wick, or a combination thereof. In some embodiments, the SL-PCM is positioned in a reservoir before moving to the thermal expansion chamber. The reservoir may be comprised of a porous material having a pore size equal to the SL-PCM surface tension quality.

In another embodiment of the of the present disclosure, a system for passively cooling a guidance system is provided. The system includes at least one active radio frequency component, a solid-liquid phase change material (SL-PCM), where the SL-PCM receives thermal energy from the at least one active radio frequency component resulting in the SL-PCM changing from a solid phase to a liquid phase, and a thermal expansion chamber, where the SL-PCM is positioned between the at least one active radio frequency component and the thermal expansion chamber, and where the liquid phase SL-PCM moves into the thermal expansion chamber.

In some embodiments, the SL-PCM is moved to the thermal expansion chamber via capillary action through at least one pore, wick, or a combination thereof. The SL-PCM may be positioned in a reservoir before moving to the thermal expansion chamber. The reservoir may be comprised of a porous material having a pore size equal to the SL-PCM surface tension quality.

The reservoir may be separated from the thermal expansion chamber by at least one wall separated by at least one wall wherein the wall comprises at least one pore, wick, or a combination thereof which enables the movement of the SL-PCM from the reservoir to the thermal expansion chamber via capillary action through at least one pore, wick, or a combination thereof.

The reservoir may be separated from the at least one active radio frequency component by at least one wall separated by at least one wall wherein the wall comprises at least one pore which enables the SL-PCM from the reservoir to contact the at least one active radio frequency component.

### BRIEF DESCRIPTION OF THE DRAWINGS

Implementations of the inventive concepts disclosed herein may be better understood when consideration is given to the following detailed description thereof. Such descriptions make reference to the included drawings, which are not necessarily to scale, and which some features may be exaggerated and some features may be omitted or may be represented schematically in the interest of clarity. Like reference numerals in the drawings may represent and refer to the same or similar element, feature, or function. In the drawings:

FIG. 1 illustrates the exterior side of a guidance system including active RF components.

FIG. 2 illustrates a sectional view of the guidance system of FIG. 1 with the solid-liquid phase change material (SL-PCM) and thermal expansion chamber in a first configuration.

FIG. 3 illustrates a sectional view of FIG. 1 with the solid-liquid phase change material (SL-PCM) and thermal expansion chamber in a second configuration.

### DETAILED DESCRIPTION

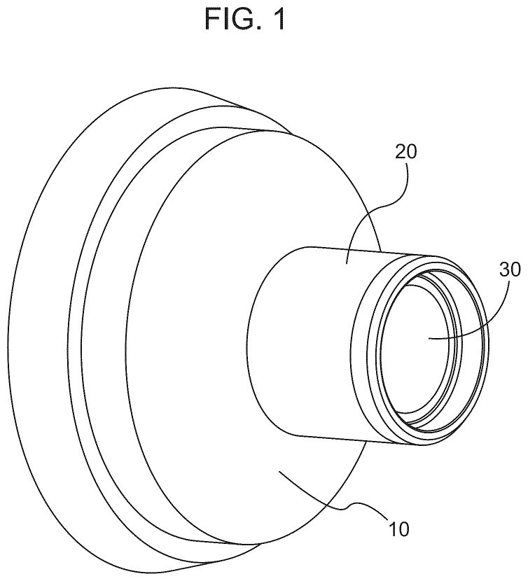

FIG. 1 shows the exterior side of a guidance system including an example of the relative positioning of active RF components (10) and a lens barrel (20) ending in an optics component (30). In operation, the majority of these components are surrounded by a housing which is not shown in FIG. 1.

RF components (10) may include, for example, antenna, amplifiers, transceivers, filters, modulators, mixers, data converters, etc. As noted above, RF components produce heat during operation.

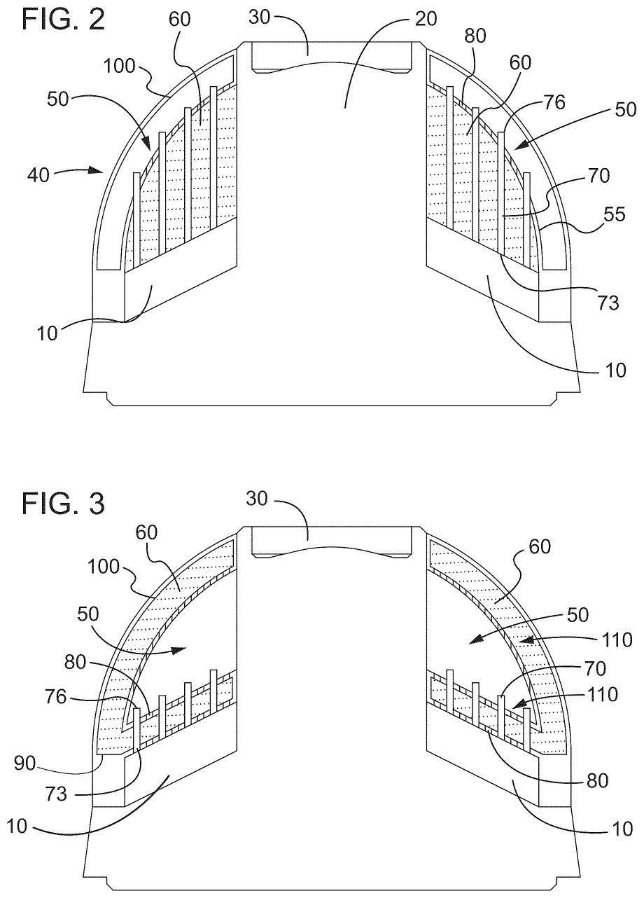

FIG. 2 shows a sectional view of a guidance system within a housing (40) including active RF components (10) similar to that shown in FIG. 1. In FIG. 2, the components of the guidance system are housed within a housing (40), for example, a radome or nosecone structure. The housing may be made of materials which are RF transparent so as not to interfere with the functionality of the RF components (10). Examples of acceptable materials include RF transparent ceramics or composites. The lens barrel (20) is positioned in the center of the housing (40) with optics component (30) positioned at the end of the lens barrel (20). Only the optics component (30) are exposed to the exterior of the housing (40).

In the configuration shown in FIG. 2, a thermal expansion chamber (50) is positioned along the interior surface (100) of the housing (40). As shown, thermal expansion chamber (50) extends along at least a portion of the interior surface (100) of the housing (40). It is envisioned that the degree to which the thermal expansion chamber (50) extends around the interior surface (100) of the housing (40) can vary as needed in a particular embodiment. Although not shown, the thermal expansion chamber (50) would be positioned in a portion of the empty area surrounding the lens barrel (20) in FIG. 1. The thermal expansion chamber (50) may be attached to the interior surface (100) of the housing (40).

The thermal expansion chamber (50) is RF transparent. RF transparency refers to a material with RF permittivity in a range of from 1 to 3. Examples of acceptable materials include RF transparent ceramics or composites. As a reference, air has a RF permittivity of 1. The thermal expansion chamber (50) may be optionally be electrically conductive or not electrically conductive.

A non-electrically conductive solid-liquid phase change material (SL-PCM) (60) is provided in thermally conductive contact with the RF components (10) and adjacent to the thermal expansion chamber (50). A portion of the SL-PCM (60) contacts the inner wall (55) of the thermal expansion chamber (50). Pores (80) are provided in an inner wall (55) of the thermal expansion chamber (50) that is spaced from the housing (40). Pores (80) provide for fluid communication between the SL-PCM and the thermal expansion chamber (50). The pores (80) have a pore size that is equal to the SL-PCM (60) surface tension quality. This relationship allows for capillary action of the SL-PCM (60) to occur though the pores (80) such that the SL-PCM (60) can move into the thermal expansion chamber (50) via the pores (80).

When in use, the SL-PCM (60) acts as a heat transfer medium. The SL-PCM (60) absorbs heat from the RF components (10) via thermal conduction which is allowed for by the positioning of the SL-PCM (60) being in thermally conductive contact with the RF components (10). The heat absorbed by the SL-PCM (60) causes it to change phases from a solid to a liquid. This phase change also results in an increase in pressure as the liquid phase of the SL-PCM (60) takes up more volume than the solid phase. The SL-PCM (60) will increase in volume by about 10%-20%, for example, about 15%. when it changes from solid phase to liquid phase. In addition, the heat energy absorbed into the SL-PCM (60) can be a further source of increase pressure.

This increase in pressure causes the SL-PCM (60), in its liquid form, to move into the thermal expansion chamber (50) though the pores (80) via capillary action. In so doing, the SL-PCM (60) removes heat from the RF components (10) and transports that heat to the thermal expansion chamber (50) which is physically spaced from the RF components (10).

Wicks (70) may also be included to facilitate transport of the SL-PCM (60) from the area near the RF components (10) to the thermal expansion chamber (50). Like pores (80), the wicks (70) have an opening diameter that is equal to SL-PCM (60) surface tension quality to allow for movement of the SL-PCM (60) though the wicks (70) via capillary action. The structure of the wicks (70) is a hollow tube. The wicks (70) may be positioned such that a first opening (73) is provided in an area near the RF components (10) and a second opening (76) is provided in thermal expansion chamber (50). Thus, the wick (70) can function to transfer the SL-PCM (60) from an area near the RF components (10) directly to the thermal expansion chamber (50). This allows the portion of the SL-PCM (60) which is in close proximity to the RF component (10) and directly absorbing heat energy from the RF component (10) to be transferred directly to the thermal expansion chamber (50) while bypassing the SL-PCM (60) in areas of the reservoir that are further from the RF component (10).

In such cases, cooler SL-PCM (60) in areas further from the RF components (10) can be drawn to the area closer to the RF component (10), because of the void cause by the movement of heated SL-PCM (60) from this closer area to the thermal expansion chamber (50) via the wick (70). This cooler SL-PCM (60) then absorbs heat from the RF component (10) and will subsequently be transferred to the thermal expansion chamber (50) via the wick (70). This cycle can repeat until all the SL-PCM (60) has been transferred to the thermal expansion chamber (50).

Additionally, pores (80) on the inner wall (55) of the thermal expansion chamber (50) can optionally allow for the flow of SL-PCM (60) out of the thermal expansion chamber (50) toward the RF components (10).

For example, circulation of the SL-PCM can be described as follows. The hot SL-PCM (60) moves from the area close to RF component (1) and collects in the thermal expansion chamber (50). The hot SL-PCM collected in the expansion chamber (50) can lose some heat energy, for example, to the housing (40). As more of the hot SL-PCM (60) is transferred to the thermal expansion chamber (50), the cooler SL-PCM (60) moves towards the area close to the RF component that has been vacated by the hot SL-PCM (60) that has been transported to the thermal expansion chamber (50) via wicks (70). Movement of the cooler SL-PCM in turn creates a void which permits some of the cooled SL-PCM (60) in thermal expansion chamber (50) to exit the thermal expansion chamber (50) and return to the area near the RF components (10), as more of the hot SL-PCM (60) is transferred to the thermal expansion chamber (50) through the pores and wicks, and then reheated by the RF components (10) to continue the circulation of the SL-PCM (60).

In this manner a cycle of SL-PCM (60) movement can occur to continuously transport heat away from the RF components (10) to the thermal expansion chamber (50) and optionally out of the system though the housing (40). It may also be the case that heat is sequestered in the terminal expansion chamber (50) such that the average temperature inside the thermal expansion chamber (50) increases as the cycle of SL-PCM (60) movement occurs.

The SL-PCM (60) is selected to have a suitable heat capacity, for example, a specific heat capacity of 2.14-2.9 J·g⁻¹·K⁻¹ and a suitable heat of fusion of 200-220 J·g⁻¹. The SL-PCM (60) is also selected to have good chemical stability and be non-corrosive. The SL-PCM should also have a relatively low melting point, for example, 20° C. to 50° C., 30° C. to 45° C., or 37° C.-40° C. Additionally, the SL-PCM should be RF transparent, i.e., have an RF permittivity of, e.g., 1 to 3.

For example, the SL-PCM selected can be a wax, such as a paraffin wax. Paraffin wax satisfies the suitable heat capacity, heat of fusion, chemical stability, low corrosivity mentioned above. Additionally, the average RF permittivity of paraffin wax is about 2.26, which is comparable to many plastics within the 2-3 range.

The above describes a passive cooling method which functions at least in part because SL-PCM (60), for example, paraffin wax, can be melted directly onto the RF components (10) as paraffin wax is both RF transparent and non-electrically conductive and would not prevent RF elements from receiving or transmitting or functioning adversely. However, the SL-PCM (60) is still sufficiently thermally conductive so as to function to prevent the critical RF components (10) from overheating.

FIG. 3 shows a different configuration of the thermal expansion chamber (50) and SL-PCM (60) from that shown in FIG. 2. Additionally, the SL-PCM (60) does not directly contact the RF components (10) but is instead, contained in a reservoir (90) structure. Reservoir (90) is thermally conductive contact, and optionally direct physical contact, with the RF components (10). The reservoir (90) is also positioned at least adjacent to the thermal expansion chamber (50). In FIG. 3, the reservoir (90) is shown as surrounding the thermal expansion chamber (50) on all but one side.

In the embodiment depicted in FIG. 3, the reservoir (90) functions to contain the SL-PCM (60), be in conductive contact with the RF components (10), and allow for movement of SL-PCM (60) from the reservoir (90) to the thermal expansion chamber (50), and optionally in the reverse direction, via pores (80) or wicks (70), as described above, or a similar functioning structure.

The barrier between the reservoir (90) and the thermal expansion chamber (50) may include pores (80) to allow for the movement of SL-PCM (60) between these two structures via capillary action. Alternatively, the reservoir (90) can comprise a porous structure which can supplement or replace the pores (80) and/or wick (70) in the function of allowing for the movement of SL-PCM (60) to and optionally from the thermal expansion chamber (50). In such configurations, at least a portion of the pores in the structure of the reservoir (90) will be a size equal to the SL-PCM (60) surface tension quality.

The reservoir (90) is constructed of a RF transparent material and is not electrically conductive. The reservoir (90) may also constructed of a thermally conductive material. Examples of acceptable materials include RF transparent ceramics or composites.

Heat generated by the RF components (10) is transferred though the reservoir (90) to the SL-PCM (60) material, for example, by conduction. This heat is absorbed by the SL-PCM (60) which causes it to undergo a phase change from a solid to a liquid. The liquid SL-PCM (60) material then travels from the reservoir (90) to the thermal expansion chamber (50) via wicks (70) and/or pores (80) via, for example, capillary action.

The reservoir (90) may also contain pores (80) and or wicks (70) positioned in the wall of the reservoir (90) directly adjacent to the RF components (10) such that the SL-PCM (60) material can pass thorough, for example, a pore (80) to directly contact the RF components (10). There may be some space between reservoir (90) and the RF components (10) which is sufficient to allow for the SL-PCM (60) to pass thorough a pore (80) to directly contact the RF components (10) and then be directly transported via capillary action though a wick (70) to the thermal expansion chamber (50) after absorbing heat from the RF components (10).

Pores (80) may be dispersed throughout the entirety of the wall or walls (110) separating the reservoir (90) and the thermal expansion chamber (50). The wall (110) may be a single wall separating the reservoir (90) and the thermal expansion chamber (50) or a double walled structure where one wall is a part of the reservoir (90) and the other wall is part of the thermal expansion chamber (50). This allows for the reservoir (90) and the thermal expansion chamber (50) to be construed modularly. In such cases, the pores (80) are present in both walls (110) and aligned to allow for the transport of SL-PCM (60) via capillary action.

Alternatively, the reservoir (90) itself may be constructed of a porous material, that is, where the structure of the reservoir (90) is a solid albeit porous material. In such embodiment, no separate wall (110) may be present as a part of the reservoir (90). A thermal expansion chamber (50) having a wall may be present. All configurations allow for the transport of SL-PCM (60) from the reservoir (90) to the thermal expansion chamber (50) at various or all portions of the reservoir (90) to efficiently remove heat from the RF components (10) and transport that heat which has been absorbed to the thermal expansion chamber (50) which is spaced from the RF components (10) by the reservoir (90). The SL-PCM (60) will only be able to be transported from the reservoir (90) while in liquid phase and not while in solid phase.

In summary, the reservoir (90) and thermal expansion chamber (50) may each have their own separate and distinct wall (110) separating each other, the reservoir (90) and thermal expansion chamber (50) may share a single wall (110) structure which divides the reservoir (90) from the thermal expansion chamber (50), or the structure of the reservoir (90) may be porous and substitute for a wall (110) separating each the reservoir (90) and thermal expansion chamber (50).

The pores (80) and/or wicks (70) may be one-way or two-way passages. For example, in one-way embodiments a valve could be used to prevent flow in one direction so as to only allow for the movement of SL-PCM (60) from the reservoir (90) to the thermal expansion chamber (50) and not in the reverse direction or vice-versa. The use of a mixture of one-way and two-way pores (80) and/or wicks (70) in the walls of the reservoir (90) and/or the walls of the thermal expansion chamber (50) is also contemplated.

A thermal barrier may optionally be placed between the lens barrel (20) and the RF components (10), the reservoir (90) or free SL-PCM (60), and the thermal expansion chamber (50), to prevent heat transfer into the lens barrel from these sources.

The reservoir (90) can be 3D printed or molded using RF transparent ceramics or composites, depending on application and required properties, for example, the reservoir (90) being porous or non-porous.

In some configurations, an enclosed system can be provided where the SL-PCM (60) is contained in a reservoir (90) directly adjacent to the RF components which functions to passively absorb heat from the RF components and transfer that heat away from the RF components and to a thermal expansion chamber (50) by the SL-PCM (60) undergoing a phase change to a liquid and moving via capillary action through wicks (70) and/or pores (80) which connect the reservoir (90) to the thermal expansion chamber (50). As such, the SL-PCM (60) is completely contained to the reservoir (90) and thermal expansion chamber (50) structures and its transfer between these structures is entirely controlled by the wicks (70) and/or pores (80).

It is conceptualized that the rate of transfer of SL-PCM (60) between the reservoir (90) and thermal expansion chamber (50) could be specifically controlled by the amount and/or positioning of the wicks (70) or pores (80). The use of wicks (70) and/or pores (80), as well as reservoirs (90) with porous construction, can therefore improve thermal management by enhancing circulation of the SL-PCM (60) via capillary action.

The above embodiments provide significant benefits over methods for cooling RF components (10) which largely rely on heat sinks and heat spreaders that are electrically conductive, and thus can only cool from the non-receiving side of the RF components (10). The embodiments described herein allow the direct cooling of the RF components (10) from the receiving side of the component with minimal to no signal attenuation. The selected SL-PCM (60), for example, paraffin wax can be a difficult material to utilize within a contained electronics package, and thus its use in the embodiments decided herein provides surprising and unexpected benefits as compared to thermal cooling techniques which are focused on more traditional materials like metals and ceramics which are less or not compatible with RF components.

### EXAMPLE

According to an exemplary embodiment, thermal and mass analysis results of an RF component (10) show the calculated total heat dissipation for the RF component to be 2.64 kJ. The required mass of paraffin wax to absorb this heat, via sensible and latent heat absorption, is from 12.7 g to 13.3 g. The volume of solid wax required is between 14.4 cubic centimeters and 15.08 cubic centimeters. The weight of solid wax required is between 0.125 newtons and 0.129 newtons.

Due to the high heat capacity, chemical stability, non-corrosive nature, and a low melting point, paraffin wax is directly applied to RF components. The melting wax absorbs the heat from the emitting side of the RF components (10), and flows into a thermal expansion chamber (50) built into the nose cone. 13.3 g of paraffin wax is used to assuredly meet the total heat dissipation of 2.64 kJ from the RF components (10). Likewise, the additional 0.129 newtons of weight of the wax is negligible considering the 100% increase in total heat absorption capacity (after factoring in heat absorption via conduction through the heatsink).

As will be appreciated by one skilled in the art, the embodiments described herein may be embodied as a method, product, or part for use in, for example, a gas turbine engine assembly. Accordingly, embodiments described herein may take the form of a portion of a gas turbine engine assembly.

The corresponding structures, material, acts, and equivalents of all means or steps plus function elements in the claims below are intended to include any structure, material, or act for performing the function in combination with other claimed elements are specifically claimed. The description of the embodiments described herein has been presented for purposes of illustration and description, but is not intended to be exhaustive or limited to the invention in the form disclosed. Many modifications and variations will be apparent to those of ordinary skill without departing from the scope and spirit of the invention. The embodiments were chosen and described in order to best explain the principles of the invention and the practical application, and to enable others of ordinary skill in the art to understand the invention for embodiments with various modifications as are suited to the particular use contemplated.

Modifications and equivalents may be made to the features of the claims without departing from the spirit or scope of the invention. Thus, it is intended that the embodiments described herein covers the modifications and variations disclosed above provided that these changes come within the scope of the claims and their equivalents.

1. A system comprising:
at least one active radio frequency component;
a non-electrically conductive solid-liquid phase change material (SL-PCM); and
a thermal expansion chamber;
wherein the SL-PCM is positioned between the at least one active radio frequency component and the thermal expansion chamber, and wherein the SL-PCM is in thermal conductive contact with the at least one active radio frequency component.

2. The system of claim 1, wherein the thermal expansion chamber is separated from the SL-PCM by a wall, wherein the wall comprises at least one pore, wick, or a combination thereof,
wherein the at least one pore and wick have a pore size equal to the SL-PCM surface tension quality.

3. The system of claim 1, further comprising a reservoir wherein the reservoir surrounds the SL-PCM.

4. The system of claim 3, wherein the reservoir and the thermal expansion chamber are separated by a wall wherein the wall comprises at least one pore, wick, or a combination thereof,
wherein the at least one pore and wick have a pore size equal to the SL-PCM surface tension quality.

5. The system of claim 3, wherein the reservoir and at least one active radio frequency component are separated by at least one wall wherein the wall comprises at least one pore, wick, or a combination thereof,
wherein the at least one pore and wick have a pore size equal to the SL-PCM surface tension quality.

6. The system of claim 3, wherein the reservoir is comprised of a porous material having a pore size equal to the SL-PCM surface tension quality.

7. The system of claim 1, further comprising a housing which encapsulates the at least one active radio frequency component, SL-PCM, and thermal expansion chamber.

8. The system of claim 7, wherein the thermal expansion chamber adjacent to the inner wall of the housing.

9. The system of claim 7, wherein the thermal expansion chamber is spaced from the housing and the at least one active radio frequency component by the SL-PCM.

10. The system of claim 7, further comprising a reservoir wherein the reservoir surrounds the SL-PCM,
wherein the thermal expansion chamber is spaced from the housing and the at least one active radio frequency component by the reservoir.

11. A method for passively cooling a guidance system comprising:
absorbing thermal energy from at least one active radio frequency component with a solid-liquid phase change material (SL-PCM),
changing the phase of the SL-PCM from a solid to a liquid, and
moving the SL-PCM to a thermal expansion chamber.

12. The method of claim 11, wherein the SL-PCM is moved to the thermal expansion chamber via capillary action through at least one pore, wick, or a combination thereof.

13. The method of claim 11, wherein the SL-PCM is positioned in a reservoir before moving to the thermal expansion chamber.

14. The method of claim 13, wherein the reservoir is comprised of a porous material having a pore size equal to the SL-PCM surface tension quality.

15. A system for passively cooling a guidance system comprising:
at least one active radio frequency component;
a solid-liquid phase change material (SL-PCM), wherein the SL-PCM receives thermal energy from the at least one active radio frequency component resulting in the SL-PCM changing from a solid phase to a liquid phase; and
a thermal expansion chamber, wherein the SL-PCM is positioned between the at least one active radio frequency component and the thermal expansion chamber, and
wherein the liquid phase SL-PCM moves into the thermal expansion chamber.

16. The system of claim 15, wherein the SL-PCM is moved to the thermal expansion chamber via capillary action through at least one pore, wick, or a combination thereof.

17. The system of claim 15, wherein the SL-PCM is positioned in a reservoir before moving to the thermal expansion chamber.

18. The system of claim 17, wherein the reservoir is comprised of a porous material having a pore size equal to the SL-PCM surface tension quality.

19. The system of claim 17, wherein the reservoir is separated from the thermal expansion chamber by at least one wall separated by at least one wall wherein the wall comprises at least one pore, wick, or a combination thereof which enables the movement of the SL-PCM from the reservoir to the thermal expansion chamber via capillary action through at least one pore, wick, or a combination thereof.

20. The system of claim 17, wherein the reservoir is separated from the at least one active radio frequency component by at least one wall separated by at least one wall wherein the wall comprises at least one pore which enables the SL-PCM from the reservoir to contact the at least one active radio frequency component.
